(19) United States
(12) Patent Application Publication
(10) Pub. No.: US 2024/0032224 A1
(43) Pub. Date: Jan. 25, 2024

(54) MULTI-DOOR ELECTRICAL EQUIPMENT ENCLOSURE WITH CABLE DOOR INTERLOCK

(71) Applicant: RON ZEITLER, SAGINAW, MI (US)

(72) Inventor: RON ZEITLER, SAGINAW, MI (US)

(21) Appl. No.: 17/813,627

(22) Filed: Jul. 20, 2022

(51) Int. Cl. H05K 5/02; E05C 7/06

(52) U.S. Cl. CPC H05K 5/0221; E05C 7/06

(57) ABSTRACT

A multi-door enclosure for housing electrical equipment has a mechanical interlock device that interacts with a main primary door of the enclosure and the existing latch mechanisms of each of the remaining secondary doors to prevent such secondary doors from being opened unless the primary door is first opened. The interlock includes a lever arm that engages and is displaced by the primary door when closed. Such movement of the lever arm is transmitted via a mechanical linkage system to move one or more latch disabling members into disabling relation with the latch mechanisms of each of the secondary doors in order to retain the latch mechanisms in their latched positions and thereby lock the secondary doors in the closed position. Opening the secondary door allows the lever arm to return to its initial position which in turn retracts the latching members and allows unlatching and opening of the secondary doors.

### CROSS-REFERENCE TO RELATED APPLICATIONS

Not Applicable.

### STATEMENT REGARDING FEDERALLY SPONSORED RESEARCH OR DEVELOPMENT

Not Applicable

Reference to Sequence Listing, a Table, or a Computer Program Listing Compact Disc Appendix

Not Applicable

### BACKGROUND OF THE INVENTION

Enclosures are often used to house various electrical and electronic equipment such as controls, instruments, components, and the like in a wide range of different environments. The enclosures serve to limit access to the equipment as well as to protect the equipment against exposure to environmental contaminants such as dust, oil, water, and the like.

Typically, large-sized enclosures are provided with multi-hinged access doors that enable those working on the equipment to access various areas of the interior of the enclosure. The doors are fitted with the usual latch mechanisms that, when latched, secure the doors in a closed position and, when unlatched, permit the doors to be swung open. The main or “primary” access door is often tied to the control switch of the incoming power supply in such way that the primary door cannot be opened unless the power supply is switched “off”.

Industry standards now also require that some means be in place to prevent the remaining “secondary” door or doors from being opened unless the primary door is first opened. In this way, none of the doors can be opened while the power is “on”. This invention is directed to such a system for multi-door enclosures.

One patent directed to this type of invention is U.S. Pat. No. 5,944,397 that issued to the inventor herein on Aug. 31, 1999 that deals with a total mechanical multi-door electrical equipment enclosure with mechanical door interlock.

The instant invention deals with a cable system replacing the mechanical latching system of the patent set forth just Supra.

### BRIEF SUMMARY OF THE INVENTION

An enclosure for housing electrical equipment constructed according to the invention includes a cabinet having a primary access door and at least one secondary access door, each being hinged to the cabinet and movable between open and closed positions. At least the secondary door is provided with a latch mechanism that, when latched, operates to secure the secondary door in the closed position. An interlock acts between the primary door and the latch of the secondary door and is operative in response to closing of the primary door to retain the latch mechanism in the latched position, thereby locking the secondary door in the closed position. The interlock is operative in response to opening of the primary door to enable movement of the latch mechanism to the unlocked position thereby permitting the secondary door to be opened.

A conventional latch mechanism 11 is shown in FIG. 3 wherein 12 is an exterior handle, 13 is a rotatable shaft for 12, 14 is a turn plate, 15 is a tongue of 11, 16 in both cases is a latch rod, 17 in both cases is a latch shoe. This latch mechanism is a prior art mechanism for use with the interlock system of the instant invention.

The invention provides a simple, mechanical solution to controlling the opening of the secondary door or doors of a multi-door enclosure. By retaining the latch mechanism in the latched position when the primary door is closed, the interlock prevents the secondary door from being opened until such time as the primary door is first opened. One attempting to open the secondary door while the primary door is closed encounters, effectively, a locked door.

The mechanical interlock system may be incorporated as a feature of new enclosure constructions or can be readily retrofitted to existing enclosures to interact with their primary doors and secondary door latch mechanisms.

According to a preferred method of the invention for controlling the opening of such multi-door enclosures having at least one such secondary door, a mechanical interlock is provided having a movable actuator supported in position to confront and be displaced by the primary door as it is closed. The actuator is coupled by a cable linkage to a latch disabling member supported adjacent the latch mechanism of the secondary door and responsive to such displacement of the actuator to move into disabling relation with the latch mechanism of the secondary door so as retain the latch mechanism in the latched position and prevent the secondary door from being opened while the primary door is closed.

### BRIEF DESCRIPTION OF THE SEVERAL VIEWS OF THE DRAWING(S)

A presently preferred embodiment of the invention is disclosed in the following description and in the accompanying drawings, wherein:

FIG. 1 is a front perspective view of a multi-door enclosure constructed according to the invention.

FIG. 2 is an inside elevational view of the enclosure taken generally along the lines 2-2 of FIG. 1.

FIG. 3 is an enlarged view of a door latch used in this invention.

FIG. 4 is a front view in perspective of a primary mechanical interlock of this invention.

FIG. 5 is a fragmentary front view in perspective of a primary mechanical interlock of this invention.

FIG. 6 is a portion of the working mechanism for the primary interlock of FIG. 5 showing the arrangement of the tension spring with the latch disabling member and the internal control assembly.

FIG. 7 is a front view in perspective of a secondary mechanical interlock of this invention.

FIG. 8 is a fragmentary view in perspective of a secondary interlock mechanism of this invention.

FIG. 9 is an enlarged view of the working mechanism for the secondary interlock of FIG. 8 showing the arrangement of the tension springs with the latch disabling member and the internal control assembly.

FIG. 10 is a view in perspective of the backside of a pulley equipped with a cable and a stop for the cable.

FIG. 11 is an illustration of the cable with a stop used in this invention.

FIG. 12 is a fragmentary front view of the pulley system of this invention

FIG. 13 is a front view in perspective of a fully assembled pulley and cable combination of this invention.

### DETAILED DESCRIPTION OF THE INVENTION AND DRAWINGS

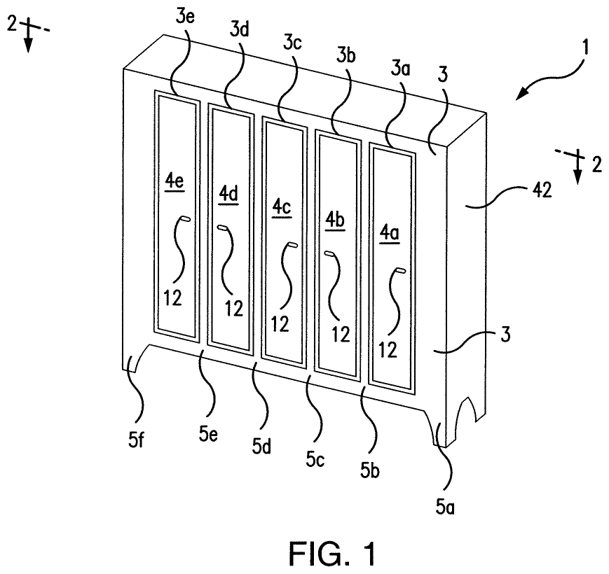

A multi-door enclosure (cabinet) constructed according to the invention is designated generally in FIG. 1 and comprises a cabinet 1 of generally rectangular box construction whose walls 2 and 2′ enclose an interior space within the cabinet for the accommodation of electrical equipment, such as electrical or electronic controls, instruments, components, and the like (not part of the invention and not shown).

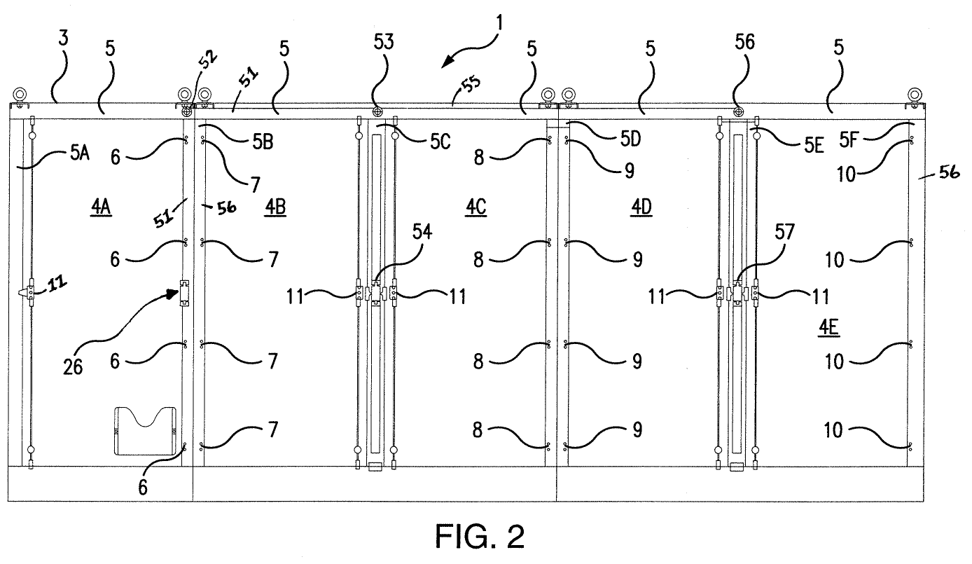

The cabinet 1 has a front wall frame 3 with a plurality of door openings 3a, 3b, 3c, 3d, and 3e in each of which is hung a door 4a, 4b, 4c, 4d, 4e, hinged along one vertical edge thereof to an adjacent vertical frame member portion of the cabinet 1, that is, adjacent vertical frame member portion 5a, 5b, 5c, 5d, 5e, and 5f, for movement between open and closed positions. Door 4a, to the right in FIG. 1 and to the left in FIG. 2, is designated the “primary” access door, while the remaining doors are designated “secondary” doors by convention. As will become apparent from the ensuing description, the invention contemplates enclosures having a primary access door 4a and at least one such secondary access door. In the embodiment shown in the drawings, there are four such secondary access doors to better illustrate the invention.

Referring to the interior elevation view of the cabinet 1 of FIG. 2, it will be seen that the primary access door 4a is hinged at points 6 on the second vertical frame portion 5b, whereas the next door 4b is hinged at points 7 on the third vertical frame 5c, the next secondary door 4c is hinged at points 8 on the fifth vertical frame 5d, the next door 4d is hinged at points 9 of the sixth vertical frame 5d, and door 4e is hinged at points 10 of the seventh vertical frame 5f.

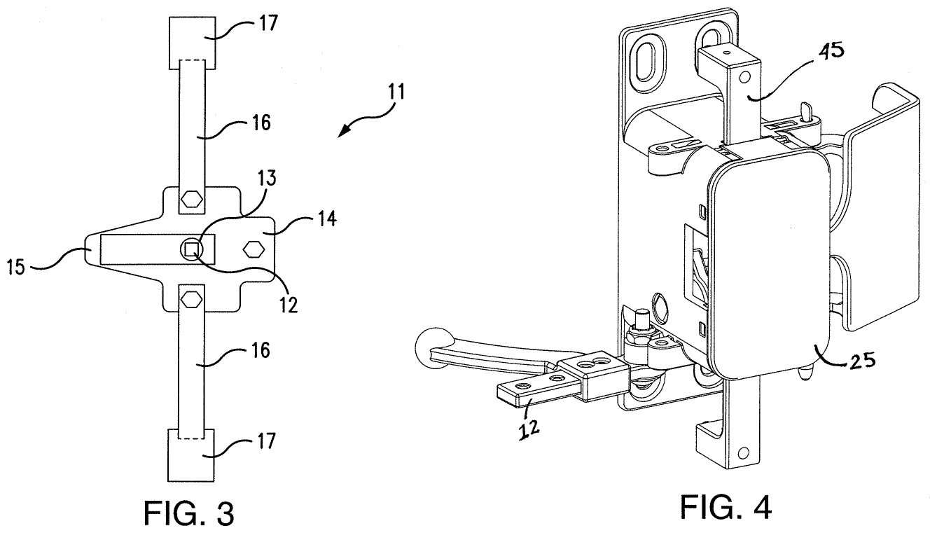

Further referring to FIGS. 2 and 3, at least the secondary doors 4b-4e and preferably the primary door 4a as well, are fitted with a latch mechanism 11. Door 4a has only a latch mechanism without any disabler mechanism. The latch mechanisms 11 for all of the doors are preferably of the same construction and operation. Door 4a has a latch mechanism 11 that has an exterior handle 12 (see FIGS. 1 and 3) mounted on a rotatable shaft 13 that extends through the associated door adjacent its swinging side. A turn plate 14 is fixed to the rotatable shaft 13 on the interior side of the door 4a and rotates with the rotatable shaft 13.

In the latched position, the handle 12 is swung vertically downwardly, positioning a projection or tongue 15 of the turn plate 14 behind the associated adjacent vertical frame sections of the front frame 3 to secure the vertical midportion of the door. The free ends of the latch rods 16 are also positioned such that shoes 17 extend beyond the top and bottom margins of the door and engage the adjacent horizontal frame members 5 of the frame 3 to secure the top and bottom regions of the door in the closed position.

To unlatch a door, the handle 12 of the latch mechanism is swung to the horizontal position which in turn rotates the tongue of the turn plate 14 out of latching engagement with its associated vertical frame section and retracts the latch rods 16 and their shoes 17 out of latching engagement with the front frame 3, thereby permitting the door to be opened.

The description and features of the closure described thus far, including the multiple hinged doors and the latch mechanisms 11 are conventional.

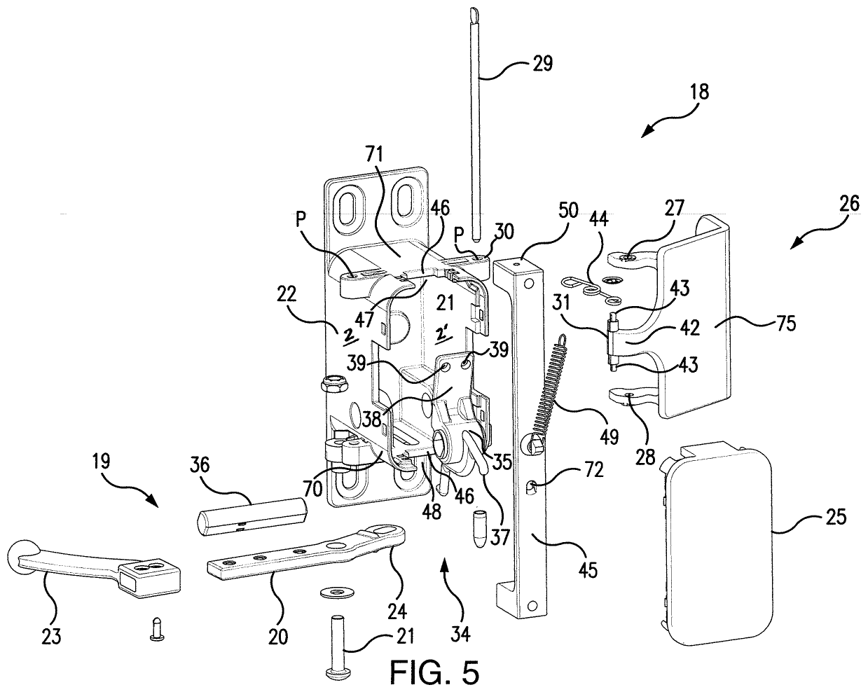

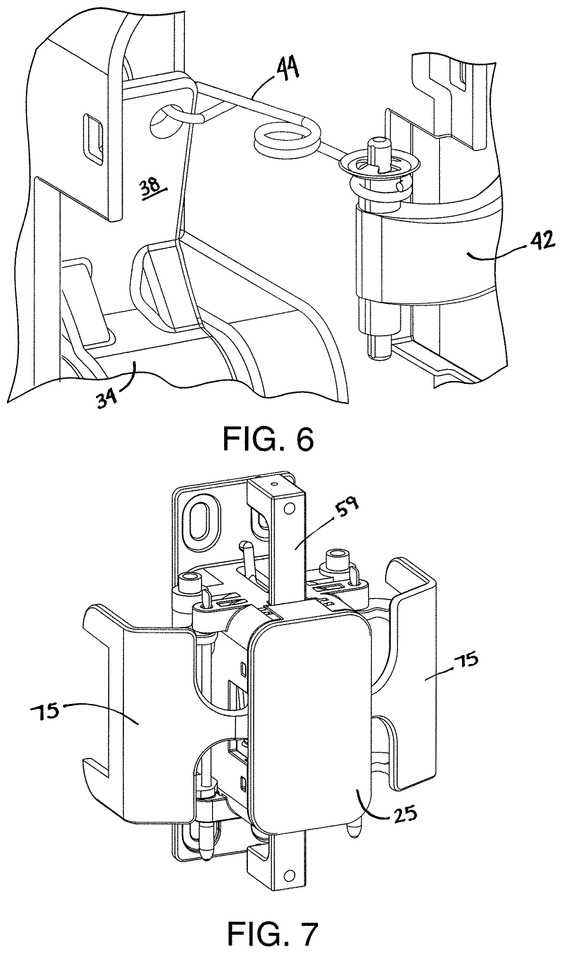

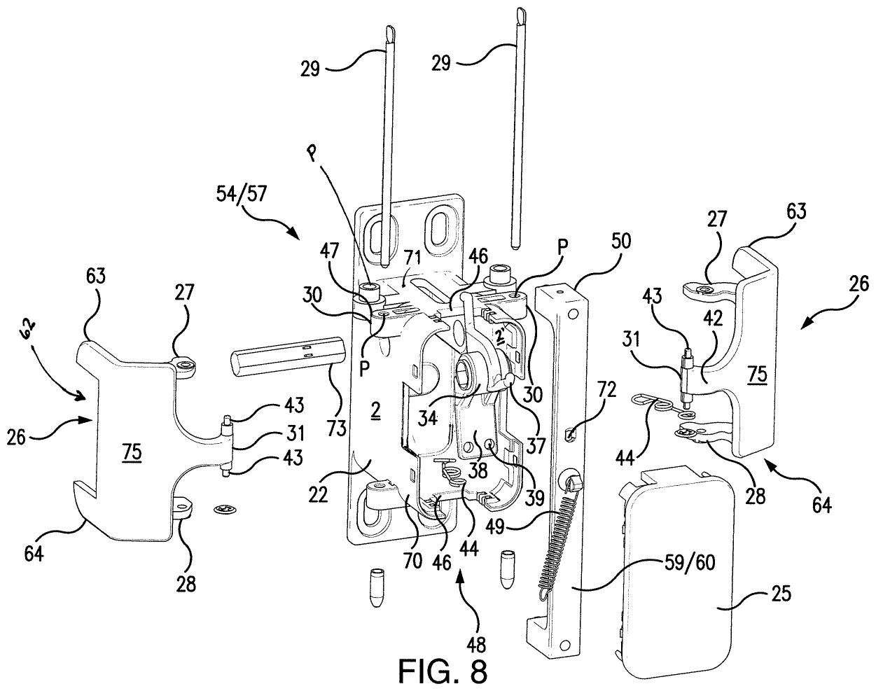

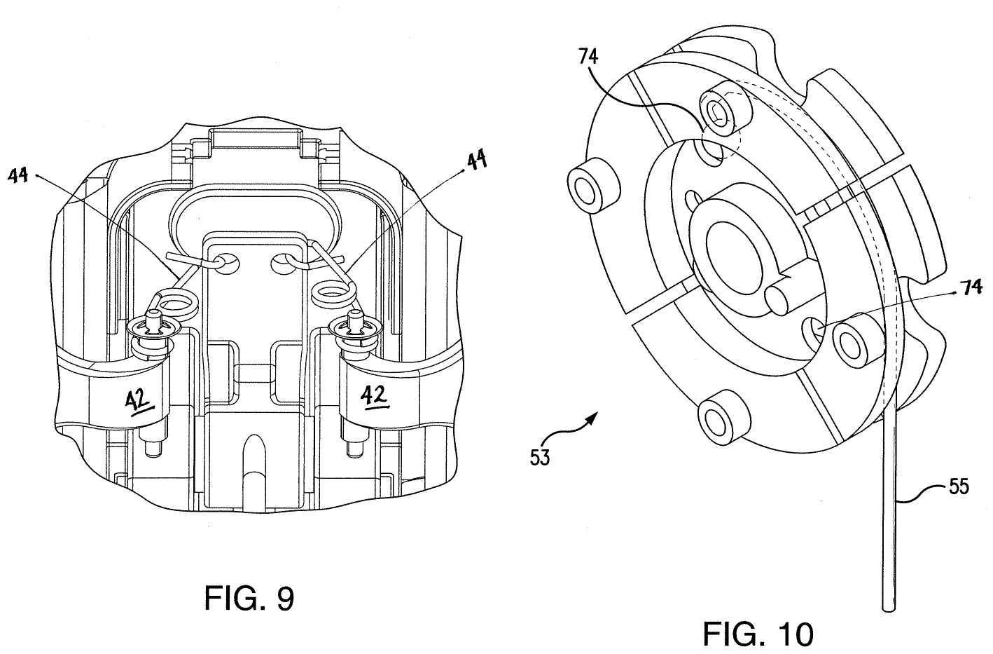

According to the invention, and with reference to FIG. 5, a primary mechanical interlock device or system 18 is provided which interacts with the primary door 4a. Secondary mechanical interlock devices 54 and 57 interact with the secondary doors 4b to 4e. The primary mechanical interlock device 18 and the secondary mechanical interlock devices 54 and 57 interact with each other and the latch mechanism 11 of each of the secondary doors in such manner as to disable such individual latch mechanisms 11 by retaining them in their latched positions while the primary door 4a is closed. In this way, the primary interlock device 18 assures that the secondary doors cannot be opened unless the primary door 4a is first opened.

Turning now to FIG. 4, which is an exploded version of a primary interlock 18. There is an actuator 19 that includes a lever arm 20 mounted on an actuator shaft 21 journaled in the housing 22 in a rotatable manner designated R. The arm 20 carries a door-engaging end 23 at its free end in spaced relation to the rotation axis R.

As the primary door 4a is swung closed, it confronts the end 23 of the lever arm 20 and pivots the lever arm 20 inwardly thereby activating the opposite end 24 of the lever arm 20, causing the internal control assembly 34 to which it is mechanically connected to rotate in a dropping motion. The dropping motion activates the internal control assembly 34 thereby trapping the latch tongue 15 with the latch disabling member 26, all of which is described in detail infra. A front cover 25 of the housing 22 extends across the side walls 2 and 2′ and end walls 70 and 71 to protect the internal workings but is shown removed in FIG. 4.

Supported adjacent each latch mechanism 11 of the secondary doors is the secondary latch disabling member 100 that is movable into and out of disabling relation or position with respect to the associated latch mechanism 11 which is discussed in detail infra.

FIG. 2 shows the secondary door 4b nearest the primary door 4a (i.e., the second door to the right in FIG. 2) is mounted with its swinging side adjacent the vertical frame portion 5c. Door 4a is hinged on vertical support member 5b. The primary latch disabling member 26 is mounted on the vertical support member 5b.

The latch disabling member 26 comprises a plate-like component 75 that is pivoted between its ends to the actuator housing 22 by legs 27, 28 and hinge pin 29. It connects to legs 30 of the housing 22 for movement relative to the housing 22 about a vertical pivot axis P. The member 26 is operatively coupled, at one end 31 thereof, to an internal control assembly 34. The internal control assembly 34 is comprised of a roller 35 mounted on a shaft 36, which shaft is supported by the housing walls 2 and 2′.

The roller 35 has mounted on its surface a prong 37. Adjacent to the prong 37 at a predetermined distance, there is mounted a connected tongue 38 with corner openings 39. The tail end 40 of the flat plate 75 is comprised of a curved extension 42 which has tabs 43 extending horizontally, the details of which are described infra.

One of such tabs 43 is mechanically connected to the corner opening 39 of the connected tongue 38 with a torsion spring 44. There is a first vertical control bar 45 surmounted on ridges 46 formed by notches 47 and 48 of the housing 22. The prong 37 is inserted through an opening 72 in the vertical control bar 45 is thereby mechanically attached.

There is extension spring 49 attached to the top surface portion of the first vertical control bar 45 and the extension spring 49 is secured at its opposite end to the housing 22. A first end 50 of the vertical control bar 45 is mechanically attached to a first cable 51 shown in FIG. 2. The first cable 51 is then strung up and over a first pulley 52 and directed to a second pulley 53 on vertical bar 5c and then to a first secondary double door mechanism 54 mounted on vertical support portion 5c. FIGS. 12 and 13 show a portion of a pulley cable system 76 wherein 77 is a rod guide base 78 is a cable pulley base 53 is a pulley 51 is a cable.

A second cable 55 is attached to the second pulley 53 and strung to a third pulley 56, over the third pulley 56 and down the vertical column 5e to a second set of double door mechanisms 57 where it is attached to a third vertical control bar 60 aligned and mounted essentially like the double door mechanisms 54.

In use, with the secondary door 4b closed and latched, subsequent closing of the primary door 4a displaces the lever arm 20 inwardly causing the actuator shaft 21 to rotate with the arm 20 in a counterclockwise direction. Such rotation of the shaft 21 turns the internal control assembly 34 such that it turns down which in turn releases the tension of the torsion spring 44 such that the latch disabling member 26 drops over the turn plate of the latch mechanism 11 and locks the doors by trapping the turn plate tongue 15 within the detent 62 between the shoulders 63 and 64.

By positioning the shoulders 63 and 64 such that they interfere with the ability to move the tongue 15 beyond the shoulders, the interlock 18 operates to retain the latch mechanism 11 in the latched position thereby disabling the latch mechanism 11 and locking the secondary door 22b in the closed position. To the extent the tongue 15 is able to move within the detent 62, its range of movement is insufficient to enable the tongue 15.

In order to open the secondary door 4b, it is necessary first to open the primary door 4a. Opening the primary door 4a allows the lever arm 20 to self-return outwardly by action of the associated torsion spring 44 to the original line position, which in turn rotates the shaft 36 clockwise, then the latch member 26 is so positioned, normal operation of the secondary door latch mechanism 11 is permitted allowing the mechanism 11 to be unlatched and the door 4b to be opened.

In the event that the secondary door 4b is inadvertently left open or is closed but not fully latched following the closing of the primary door 4a, the interlock 18 is designed to permit subsequent closing and latching of the secondary door 4b without having first to re-open the primary door 4a. The torsion spring 44 of the latch disabling member 26 is sufficiently rigid to transmit motion between the shaft 36 and latch disabling member 26, yet it is sufficiently resilient to enable the latch disabling member 26 to pivot independently of the movement of the lever arm 20 and shaft 36 between the disabling and enabling positions to accommodate such subsequent closing and latching of the secondary door 4b as necessary. All that is required is that the secondary door 4b be swung closed and the latch mechanism 11 rotated to the latched position. Moving the mechanism 11 to the latched position rotates the tongue 15 into engagement with the camming surface 63 of the bottom-most ear portion 64, causing the latch disabling member 26 to deflect initially inwardly in opposition to the spring 44. As the connecting tongue 38 passes the ear 64, it drops into the detent 62, whereupon the latch disabling member 26 is returned by the spring 44 back to the disabling position to trap the connecting tongue 38 in the latched position to prevent subsequent re-opening of the secondary door 4b. Such an action appertains to doors 4b, 4c, 4d, and 4e.

Thus far, the construction and operation of the interlock 18 has been concerned with controlling the opening of just the secondary door 4b located immediately adjacent the primary door 4a. For enclosures 1 having more than one secondary door 4b, as in the case of the illustrated embodiment in which there are three such additional secondary doors 4c, 4d, and 4e, the interlock 18 includes additional latching units coupled to the actuator 19 by the cable linkage system 51 and 55, to interact in the same manner with the latching mechanisms 11 of such additional secondary doors 4b, 4c, 4d, and 4e.

The three additional secondary doors 4c, 4d, and 4e are mounted such that their swinging sides are adjacent one another along the vertical frame portions 5c and 5e of the cabinet 1. As such, the respective latch mechanisms 11 are adjacent one another on opposite sides of the frame portion 5c and 5e.

Interfacing with the latch mechanisms 11 are a first double interlock assembly 54 mounted at vertical support member 5c and a second double interlock assembly 57 mounted at vertical support member 5e. The roller 35 therein is supported by a shaft 73 which is supported through the walls 2 and 2′ of the housing 22. Mechanical attachments for the first double interlock assembly 54 are identical to the mechanical attachments for the primary interlock assembly 18.

The latch disabling member 26 comprises a plate-like component 75 that is pivoted between its ends to the actuator housing 22 by legs 27, 28 and hinge pin 29. It connects to legs 30 of the housing 22 for movement relative to the housing 22 about a vertical pivot axis P. The member 26 is operatively coupled, at one end 31 thereof, to an internal control assembly 34. The internal control assembly 34 is comprised of a roller 35 mounted on a shaft 73, which shaft is supported by the housing walls 2 and 2′.

The roller 35 has mounted on its surface a prong 37. Adjacent to the prong 37 at a predetermined distance, there is mounted a connected tongue 38 with corner openings 39. The tail end 40 of the flat plate 75 is comprised of a curved extension 42 which has tabs 43 extending horizontally, the details of which are described infra.

One of such tabs 43 is mechanically connected to the corner opening 39 of the tongue 38 with a torsion spring 44. There is a second vertical control bar 59 surmounted on ridges 46 formed by notches 47 and 48 of the housing 22. The prong 37 is inserted through an opening 72 in the second vertical control bar 59 and is thereby mechanically attached. Note that there are openings 72 in the second vertical control bar 59 and the third vertical control bar 60.

There is extension spring 49 attached to the top surface portion of the second vertical control bar 59 and the extension spring 49 is secured at its opposite end to the housing 22.

The second pulley 53 on vertical bar 5c has attached to it (the details of which can be found infra) a second cable 55 that is strung to a third pulley 56, over the third pulley 56 and down the vertical column 5e to a second set of double door mechanisms 57 where it is attached to a third vertical control bar 60 aligned and mounted essentially like the double interlock assembly 54.

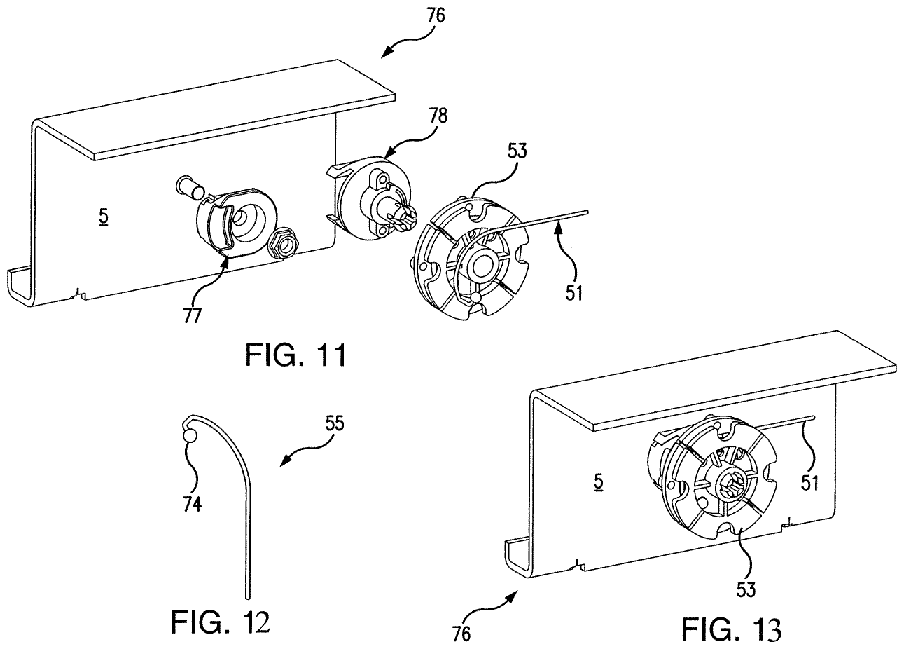

It should be understood that the cable 51 is just supported over the top of pulley 52 without any direct connection to pulley 52 itself. The same is true for cable 51 and pulley 53 wherein the cable 51 is just turned over pulley 53 as well. Cable 55 is physically connected to pulley 53 and cable 55 is just rolled over pulley 56. For purpose of this invention and with regard to FIG. 11, there is shown a cable that is constructed for purposes of this invention showing the cable 55 and a stop 74 for the cable 55 which is generally molded metal. Figure is a view in perspective of the backside of pulley 53 of this invention showing the configuration used to trap the cable in the pulley wherein the cable is 53, the stop 74, and the openings for stop 74.

Turning now to the pulley system 76 of this invention as illustrated in FIGS. 11 and 12, there is shown in FIG. 11 a guide base 77, a cable pulley base 78 (a pulley stay) and a pulley, for example, pulley 53 with a cable, for example cable 51.

The pulley stay 78 provides a bearing shaft for the pulley to rotate on, and holds the appropriate stand-off distance for the pulley 53. It also provides four barbs 79 that allow the pulley to snap into place and be retained so that it can't come off in use.

The disclosed embodiments are representative of a presently preferred form of the invention but is intended to be illustrative rather than definitive thereof. The invention is defined in the claims.

What is claimed is:

1. An enclosure for housing electrical equipment comprising:
a cabinet having a primary access door and at least one secondary access door, said doors being hinged to said cabinet and movable between open and closed positions, at least said secondary door having a latch mechanism movable between latched and unlatched positions to secure said secondary door releasably in said closed position when latched, and to permit said secondary door to be opened when unlatched, and a mechanical interlock acting between said primary door and said latch mechanism of said secondary door, said mechanical interlock including an actuator supported adjacent said primary door in position to confront and be displaced by said primary door upon closing said primary door, and a latch disabling member operatively coupled to said actuator and moveable about a pivot axis in response to said displacement of said actuator into a latch disabling position to retain said latch mechanism in said latched position thereby locking said secondary door in said closed position, and being operative in response to opening said primary door to enable movement of said latch mechanism from said latched position to said unlatched position thereby permitting said secondary door to be opened.

2. The enclosure of claim 1 wherein said mechanical interlock includes a mechanical linkage operatively coupling said actuator to said latch disabling member.

3. The enclosure of claim 2 wherein said cabinet includes a plurality of said secondary doors and an associated plurality of said latch mechanisms, said mechanical interlock including a plurality of said latch disabling members operatively coupled by said mechanical linkage to said actuator for conjoint movement into and out of said disabling relation with said latch mechanisms.

4. The enclosure of claim 3 wherein said mechanical linkage includes an overhead shaft supported for rotation by said cabinet above said secondary doors and operatively coupled by a first connecting rod to said actuator in such manner as to cause said shaft to rotate in response to movement of said actuator, and operatively coupled by at least one additional connection rod to at least one of said plurality of said latch disabling members in such manner as to move said latch disabling members conjointly into and out of said disabling relation with said latch mechanism in response to rotation of said overhead shaft.

5. The enclosure of claim 2 wherein said actuator includes a lever arm swingable about a rotation axis and a door-engaging portion spaced from said axis positioned to confront said primary door when closed to rotate said lever arm in a first direction about said axis.

6. The enclosure of claim 5 wherein said mechanical linkage transmits said rotational displacement of said lever arm into pivotal movement of said latch disabling member.

7. The enclosure of claim 5 wherein said pivot axis of said latch disabling member lies transverse to said rotation axis of said lever arm.

8. The enclosure of claim 5 wherein said latch disabling member includes a catch portion engageable with a movable portion of said latch mechanism, when in said disabling relation therewith, to secure said latch mechanism in said latched position.

9. The enclosure of claim 8 wherein said catch portion includes at least one ear projection having a shoulder extendible into confronting engagement with said movable portion when said latch disabling member is pivoted into said disabling relation with said latch mechanism.

10. The enclosure of claim 9 wherein said catch portion comprises a pair of said ear projections spaced to provide a detent therebetween trapping said movable portion against movement with said latch mechanism to said unlatched position when said latch disabling member is pivoted into said disabling relation with said latch mechanism.

11. The enclosure of claim 10 wherein said linkage includes a spring acting on said latch disabling member to urge said latch disabling member constantly toward said disabling relation with said latch mechanism and permitting said latch disabling member to pivot independently of the movement of said actuator.

12. The enclosure of claim 11 wherein said latch disabling member includes a camming surface adjacent said catch positioned to confront and be displaced by said movable member of said latch mechanism when said primary door is closed and, upon movement of said latch mechanism from said unlatched position to said latched position, to accommodate closing and latching of said secondary door subsequent to said closing of said primary door.
